(19) United States
(12) Patent Application Publication
(10) Pub. No.: US 2013/0157409 A1
(43) Pub. Date: Jun. 20, 2013

(54) SELECTIVE ATOMIC LAYER DEPOSITION OF PASSIVATION LAYERS FOR SILICON-BASED PHOTOVOLTAIC DEVICES

(71) Applicants: Kaushik VAIDYA, Bangalore (IN); Hari K. PONNEKANTI, San Jose, CA (US)

(72) Inventors: Kaushik VAIDYA, Bangalore (IN); Hari K. PONNEKANTI, San Jose, CA (US)

(21) Appl. No.: 13/715,767

(22) Filed: Dec. 14, 2012

Related U.S. Application Data
(60) Provisional application No. 61/576,864, filed on Dec. 16, 2011.

(51) Int. Cl. H01L 31/18

(52) U.S. Cl. CPC H01L 31/18
USPC 438/98

(57) ABSTRACT

Embodiments of the invention generally provide methods for forming a silicon-based photovoltaic device. In one embodiment, a method includes forming a pattern inhibitor layer on a back surface of a substrate, wherein the pattern inhibitor layer covers a first portion of the back surface and a second portion of the back surface remains substantially free of the pattern inhibitor layer. The method further includes forming a passivation layer containing aluminum oxide on the second portion of the back surface and maintaining the pattern inhibitor layer substantially free of the passivation layer during a selective atomic layer deposition (S-ALD) process. Additionally, the method includes removing the pattern inhibitor layer from the back surface to reveal the first portion of the back surface and subsequently forming a contact layer on the first portion of the back surface.

### CROSS-REFERENCE TO RELATED APPLICATIONS

This application claims benefit of U.S. provisional patent application No. 61/576,864, filed Dec. 16, 2011, which is hereby incorporated by reference.

### BACKGROUND OF THE INVENTION

1. Field of the Invention

Embodiments of the invention generally relate to methods for fabricating photovoltaic devices, and more particularly to methods for selective atomic layer deposition of passivation layers on the back surfaces of silicon-based solar substrates.

2. Description of the Related Art

Solar cells are photovoltaic devices that convert sunlight directly into electrical power. The most common material utilized in a solar cell is silicon, which is generally in the form of single crystalline silicon, polycrystalline silicon, or amorphous silicon. The ratio of light converted into electrical power versus the amount of light shined on the front or light-receiving surface of the solar cell is a measurement of the efficiency of the solar cell. Improvements in fabricating techniques undertake the task of increasing the overall efficiency of a solar cell, while maintaining or reducing the cost to manufacture.

The efficiency of the solar cell may be enhanced by use of a passivation layer on the rear surface of a solar cell. When light passes from one medium to another, for example from air to glass, or from glass to silicon, some of the light may reflect off of the interface between the two media. The fraction of light reflected is a function of the difference in refractive index between the two media, wherein a greater difference in refractive indices of two adjacent media results in a higher fraction of light being reflected from the interface therebetween. Various layers disposed on the rear surface of the solar cell can reflect light back into the silicon where the reflected light can be absorbed, such as caused by the interface between two media, and increase the efficiency of a solar cell.

The efficiency at which a solar cell converts incident light energy into electrical energy is adversely affected by a number of factors. Such factors include the fraction of incident light reflected off the light receiving surface of a solar cell, the fraction of incident light not reflected off the rear surface of the solar cell, any other incident light not absorbed in the cell structure, and the recombination rate of electrons and holes within the solar cell. Each time an electron-hole pair recombines, a charge carrier is eliminated, thereby reducing the efficiency of the solar cell. Recombination may occur in the bulk silicon of a substrate, which is a function of the number of defects in the bulk silicon, or on the surface of a substrate, which is a function of how many non-terminated chemical bonds are on the substrate surface. Moreover, the efficiency of the solar cell may be reduced due to a reduction in the carrier lifetime caused by a shunt current created at the rear surface of the solar cell. The shunt current is formed by a buildup of excess negative charge near the rear surface of the solar cell due to the presence of an unwanted amount of positive charge in adjacent dielectric or passivation layers. The excess negative charge can leak into the nearby backside contacts causing recombination to occur at the contact interface, thereby reducing solar cell efficiency.

One function of a passivation layer is to minimize the carrier recombination at the rear surface a solar cell. One way to improve the passivation function of a passivation layer is to have a sufficient source of hydrogen available in the passivation layer for bulk and surface passivation. Another way to improve the passivation layer function is to provide a negative charge or a limited amount of net positive charge in the passivation layer to prevent the formation of a shunt current. Shunt current is an undesirable electrical short circuit between the front and back surface contacts of the solar cell. Thorough passivation of a solar cell by using a passivation layer greatly improves the efficiency of the solar cell by reducing recombination rates. Patterning, however, of a rear surface passivation layer, such as when forming backside contacts, may also be difficult depending on the type of patterning processes used and type of passivation layer, resulting in slower throughput. Moreover, conventional passivation layer formation processes have been unable to provide a passivation layer having a desired amount of charge to prevent or at least reduce shunt current formation.

Current processes of crystalline silicon solar cell processing involve the deposition of a blanket passivation layer followed by the opening of holes or features in the layer by use of high-energy lasers or reactive chemicals. The opened features are filled with metallic material to form electrical contact with the silicon substrate allowing current collection and transport. This process sequence of opening features in the passivation layer and filling the features with metallic material is the subtractive processing approach adapted from the integrated circuit processing industry. Although this approach may be used to fabricate solar cells, there are many negative aspects involved with this multi-step process, including the use of corrosive chemical etchants and/or high-energy lasers, as well as additional cleaning and drying steps which increase cost and reduce overall throughput.

Therefore, there is a need for a method for preparing a rear surface passivation layer that prevents shunt current formation, for simplifying the patterning of the back layer contact, for cleaner interfaces between contact and silicide layers that lower contact resistance at the silicide, and for improving throughput and reducing cost of the manufactured photovoltaic device having improved solar efficiency.

### SUMMARY OF THE INVENTION

Embodiments of the invention generally relate to methods for fabricating photovoltaic devices, and more particularly relate to a dielectric passivation and metallization process sequence that includes a selective atomic layer deposition (S-ALD) process utilized to form a passivation layer on the back surface of a silicon-based substrate. The method provides a dielectric passivation and metallization process sequence to enable volume manufacturing of a high efficiency crystalline silicon solar cell at an increased throughput.

In one embodiment, a method includes forming a pattern inhibitor layer on a back surface of a substrate, wherein the pattern inhibitor layer covers a first portion of the back surface and a second portion of the back surface remains substantially free of the pattern inhibitor layer. The method includes forming a passivation layer containing aluminum oxide on the second portion of the back surface while maintaining the pattern inhibitor layer substantially free of the passivation layer during an S-ALD process. The method further includes removing the pattern inhibitor layer from the first portion of the back surface and subsequently, forming a contact layer on the first portion of the back surface. The aluminum oxide material of the passivation layer provides a negative charge within the layer which prevents or greatly reduces the formation of undesirable shunt currents throughout the photovoltaic device.

In another embodiment, the method includes forming a pattern inhibitor layer on a back surface of a substrate, wherein a positive pattern of the back surface is covered by the pattern inhibitor layer and a negative pattern of the back surface is substantially free of the pattern inhibitor layer. The method further includes forming a passivation layer containing aluminum oxide on the back surface within the negative pattern and maintaining the pattern inhibitor layer substantially free of the passivation layer during an S-ALD process. Thereafter, the method includes removing the pattern inhibitor layer from the back surface to expose or reveal the positive pattern of the back surface. Once the pattern inhibitor layer has been removed, a contact layer is formed on the back surface within the positive pattern encompassed by the passivation layer.

The pattern inhibitor layer is printed, deposited, or otherwise formed on the back surface of the substrate by a microcontact-printing (pCP) process, a screen-printing process, or other similar process or technique. In some examples, the pattern inhibitor layer is formed during a microcontact-printing process. The microcontact-printing process includes contacting the first portion of the back surface of the substrate with an inhibitor solution contained on a pattern stamp while forming the pattern inhibitor layer. The inhibitor solution contains the corresponding inhibitor compounds contained within the pattern inhibitor layer. Self-assembled monolayer (SAM) compounds are an exemplary group of compounds utilized as the inhibitor compounds. Generally, the SAM compounds are hydrophobic SAM compounds, such as octadecyltrichlorosilane (ODTS) or derivatives thereof. In other examples, the pattern inhibitor layer is formed during a screen-printing process by applying the inhibitor compound to the first portion of the back surface of the substrate.

The pattern inhibitor layer is removed from the first portion of the back surface of the substrate while the passivation layer is maintained on the second portion of the back surface. The pattern inhibitor layer may be exposed to and dissolved by a solvent while being removed from the back surface of the substrate. Solvents utilized to dissolve or otherwise remove the pattern inhibitor layer include organic solvents, aqueous solvents, or combinations thereof. Exemplary solvents include water, acetone, methyl ethyl ketone, diethyl ketone, benzene, toluene, xylene, derivatives thereof, mixtures thereof, or combinations thereof.

The passivation layer containing aluminum oxide is deposited or otherwise formed by sequentially exposing the back surface of the substrate to an aluminum precursor gas and an oxidizing reagent gas while depositing the aluminum oxide on the second portion of the back surface during an S-ALD process. In one example, the aluminum precursor gas contains trimethyl aluminum and the oxidizing reagent gas contains water vapor. The passivation layer generally has a thickness within a range from about 1 nm to about 500 nm, more narrowly within a range from about 5 nm to about 200 nm, and more narrowly within a range from about 20 nm to about 80 nm.

The contact layer contains at least one conductive material, such as a metallic material, a metal silicide material, or combinations thereof. The conductive material contained within the contact layer generally has at least one metal, such as aluminum, silver, gold, copper, nickel, silicides thereof, alloys thereof, or combinations thereof. In some examples, the contact layer contains aluminum and silver. The contact layer may be formed by depositing, applying, or otherwise disposing a metallic paste on the first portion of the back surface of the substrate within the contact pattern. Subsequently, the metallic paste in contact with the silicon surface of the substrate is heated to form the contact layer containing a metallic silicide material during a silicidization process. In one example, a metallic paste containing aluminum and silver is disposed onto the first portion of the silicon-containing back surface and within the contact pattern. During a subsequent silicidization process, the substrate is heated to form the contact layer containing an aluminum silver silicide.

The substrate is generally a silicon substrate or at least contains silicon or a silicon-based material. Therefore, the back surface of the substrate is generally a silicon surface or a silicon-based surface and the contact layer is formed thereon. Prior to forming the pattern inhibitor layer, a preclean may optionally be utilized to remove native oxides and/or contaminants from the back surface of the substrate. The front surface of the substrate generally contains a solar device or multiple solar devices disposed thereon and is usually referred to as the light receiving surface.

### BRIEF DESCRIPTION OF THE DRAWINGS

So that the manner in which the above recited features of the invention can be understood in detail, a more particular description of the invention, briefly summarized above, may be had by reference to embodiments, some of which are illustrated in the appended drawings. It is to be noted, however, that the appended drawings illustrate only typical embodiments of this invention and are therefore not to be considered limiting of its scope, for the invention may admit to other equally effective embodiments.

FIG. 1 is a flow chart illustrating a passivation and metallization process sequence as described by embodiments herein.

FIGS. 2A-2F depict exemplary cross-sectional views of a substrate after being processed at different steps of a passivation and metallization process sequence, as described by embodiments herein.

FIGS. 3A-3C depict exemplary views of a substrate after being processed at different steps while forming a pattern inhibitor layer on a back surface of the substrate during a microcontact-printing process, as described by embodiments herein.

FIGS. 3D-3G depict exemplary views of the substrate depicted in FIGS. 3A-3C after being processed at different steps of a passivation and metallization process sequence, as described by embodiments herein.

### DETAILED DESCRIPTION

Embodiments of the invention generally relate to methods for fabricating photovoltaic devices, and more particularly relate to a dielectric passivation and metallization process sequence that includes a selective atomic layer deposition (S-ALD) process utilized to form a passivation layer on the back surface of a silicon-based substrate. The passivation layer is deposited or otherwise formed on selective areas of the back surface of the substrate by the S-ALD process, and subsequently, a metallization contact layer is directly formed on the non-passivated area on the back surface of the substrate. Prior to depositing the passivation layer, a pattern inhibitor layer is printed or otherwise formed on the back surface of the substrate. The pattern inhibitor layer covers a first portion of the back surface and a second portion of the back surface remains substantially free of the pattern inhibitor layer. Thereafter, during the S-ALD process, the passivation layer containing aluminum oxide is selectively deposited on the second portion of the back surface while the pattern inhibitor layer remains substantially free of the passivation layer. After the S-ALD process, the pattern inhibitor layer is removed from the first portion of the back surface and the contact layer is formed on the first portion of the back surface. The direct deposition or formation of the contact layer on the silicon substrate provides for subsequent metallurgical bond formation during a later sintering step, such as by a silicidization process. The dielectric passivation and metallization process sequence provides volume manufacturing of high efficiency crystalline silicon solar cells at an increased throughput.

Microcontact-printing (pCP), screen-printing, or other techniques are utilized to directly print, deposit, or otherwise form the pattern inhibitor layer on the back surface of the substrate. Unlike the conventional processes, the methods described herein eliminate the need for selective area opening after a blanket deposition of passivation layer, avoid complicated metallization techniques involving combined metal deposition techniques, and also provide a reduction of overall process steps.

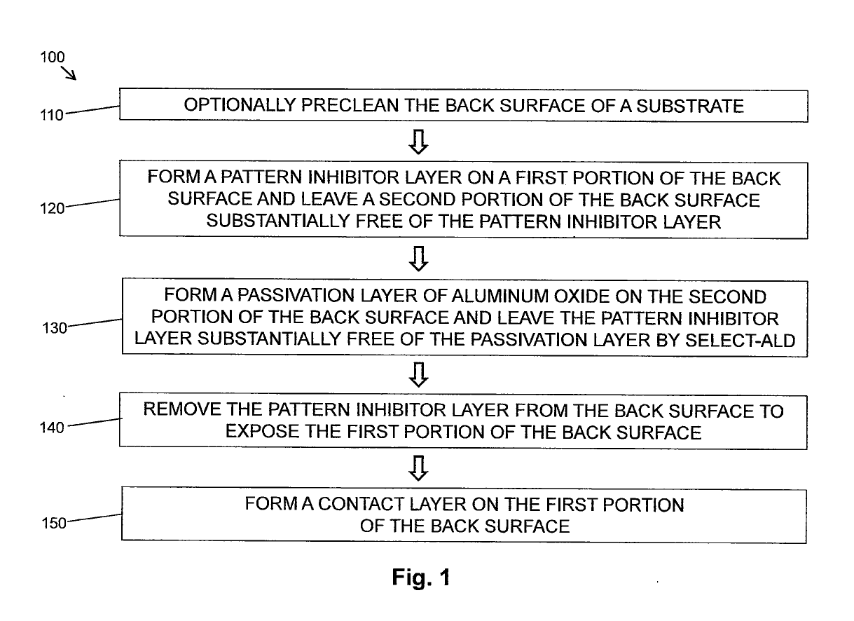

FIG. 1 is a flow chart illustrating process 100, which is a method for forming passivation and contact materials on a substrate surface with a passivation and metallization process sequence, as described by embodiments herein. The steps of process 100 include forming passivation and contact materials on the back surface of a silicon substrate generally utilized in solar applications. Process 100 includes an optional preclean of the back surface of the substrate in step 110, forming a pattern inhibitor layer on a first portion of the back surface while leaving a second portion of the back surface substantially free of the pattern inhibitor layer in step 120, and forming a passivation layer containing aluminum oxide on the second portion of the back surface while leaving the pattern inhibitor layer substantially free of the passivation layer during an S-ALD process in step 130. Process 100 further includes removing the pattern inhibitor layer from the back surface to expose the first portion of the back surface in step 140 and forming a contact layer on the first portion of the back surface in step 150.

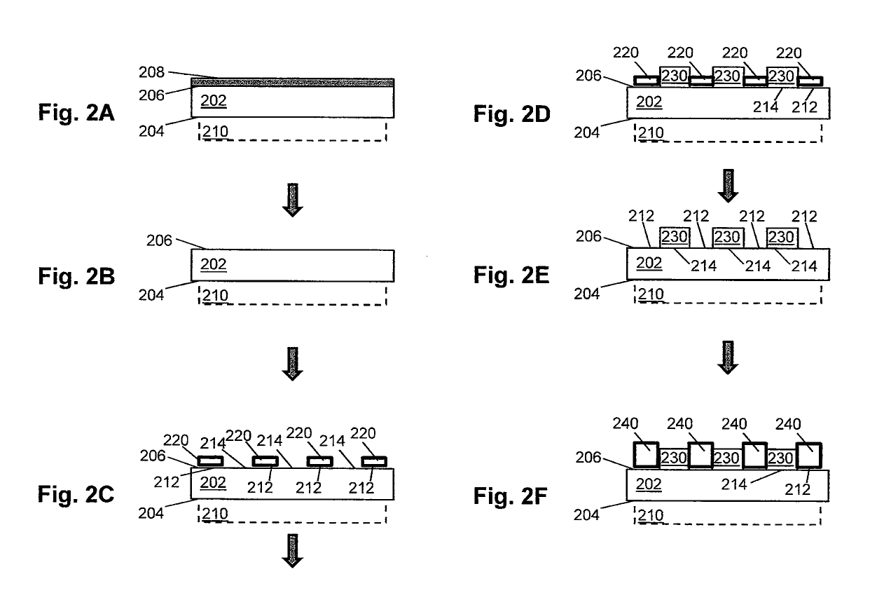

FIGS. 2A-2F depict exemplary cross-sectional views of a substrate 202 after being processed at various steps of a passivation and metallization process sequence, such as steps 110-150 of process 100, as described by embodiments herein. FIG. 2A depicts the substrate 202 having a front surface 204 opposite a back surface 206. The substrate 202 is generally a silicon substrate or at least contains silicon or a silicon-based material. Therefore, the front surface 204 and/or the back surface 206 of the substrate 202 may each independently be a silicon surface or contain a silicon-based material.

The front surface 204 of the substrate 202 generally contains a solar device 210 or multiple solar devices disposed thereon. The front surface 204 may contain a variety of photovoltaic cells including single junction photovoltaic cells, tandem junction photovoltaic cells, or multi-junction photovoltaic cells. The front surface 204 is usually referred to as the light receiving surface or side of the substrate 202, since each solar device 210 disposed on the front surface 204 generally has a light receiving surface.

Prior to starting the passivation and metallization process sequence, the back surface 206 of the substrate 202 may need to be exposed to a preclean step for removing native oxides or contaminants thereon. One or more contaminants 208 may be disposed on the back surface 206 of the substrate 202, as depicted in FIG. 2A. Exemplary contaminants 208 include native oxides, halogens, residues, particles, and/or other contaminants. Step 110 of process 100 is an optional preclean step utilized to remove contaminants 208 from the back surface 206 of the substrate 202. FIG. 2B depicts the back surface 206 of the substrate 202 free of contaminants 208, including free of native oxides, subsequent to the preclean step. Alternatively, step 110 may be excluded from process 100, which then starts the passivation and metallization process sequence at step 120.

The preclean process at step 110 may be conducted in a single processing step or in multiple, separate processing steps and the preclean process may be conducted in a single processing chamber or in multiple, separate processing chambers. The preclean process may be a wet-clean process in which the back surface 206 of the substrate 202 is exposed to clean solutions, such as HF-last solutions, SC1 clean solutions, SC2 clean solutions, buffered oxide etch (BOE) solutions, as well as other solutions. In one example, a wet-clean process utilizes an HF-last solution containing water, HF, and optional additives including chelators, surfactants, reductants, other acids or combinations thereof. In another example of a preclean process, a buffered oxide etch (BOE) solution is used to remove native oxides and other contaminants from the back surface 206 during step 110. An exemplary wet-clean system for conducting the wet-clean process includes a TEMPEST™ wet-clean system, available from Applied Materials, Inc., located in Santa Clara, Calif.

In other examples, the substrate 202 is exposed to a plasma etch process or a plasma clean process to remove contaminants 208 from the back surface 206 during step 110. A plasma cleaning processes may be performed using a vacuum preclean chamber, such as a SICONI™ Preclean chamber and process, both available from Applied Materials, Inc., located in Santa Clara, Calif. Further description of a plasma-assisted dry etch chamber and plasma etch process that may be used by embodiments herein is disclosed in commonly assigned U.S. Ser. No. 11/063,645, filed on Feb. 22, 2005, and published as US 2005-0230350, and U.S. Ser. No. 11/192,993, filed on Jul. 29, 2005, and published as US 2006-0033678, which are hereby incorporated by reference in their entirety to the extent not inconsistent with the claimed invention.

Step 120 of process 100 includes printing, depositing, or otherwise forming a pattern inhibitor layer 220 on a first portion 212 of the back surface 206 of the substrate 202 while leaving a second portion 214 of the back surface 206 substantially free of the pattern inhibitor layer 220, as depicted in FIG. 2C. The first portion 212 of the back surface 206 is covered with the pattern inhibitor layer 220. The first portion 212 generally provides a positive pattern or a contact pattern for accommodating the contact layer 240 once formed on the back surface 206. The second portion 214 of the back surface 206 remains completely free or substantially free of the pattern inhibitor layer 220 during step 120. The second portion 214 generally provides a negative pattern or a passivation pattern for accommodating the passivation layer 230 once formed on the back surface 206.

In some examples, the first portion 212 of the back surface 206 has a pattern of the contact layer 240 (e.g., contact pattern or a negative pattern of the passivation layer 230) and the second portion 214 of the back surface 206 has a pattern of passivation layer 230 (e.g., passivation pattern or a negative pattern of the contact layer 240). The first portion 212 of the back surface 206 generally has a surface area ratio within a range from about 0.5% to about 30%, more narrowly within a range from about 1% to about 20%, for example, from about 2% to about 10% of the back surface 206. The second portion of the back surface 206 generally has a surface area ratio within a range from about 70% to about 99.5%, more narrowly within a range from about 80% to about 99%, for example, from about 90% to about 98% of the back surface 206.

The pattern inhibitor layer 220 is printed, deposited, or otherwise formed on the back surface 206 of the substrate 202 by a microcontact-printing (pCP) process, a screen-printing process, or another printing or deposition process during step 120. In some examples, the pattern inhibitor layer 220 is formed during a microcontact-printing process. The microcontact-printing process includes exposing a pattern stamp to an inhibitor solution and then contacting the pattern stamp to the first portion 212 of the back surface 206. The inhibitor solution contained on the pattern stamp forms the pattern inhibitor layer 220 on the first portion 212 of the back surface 206. The inhibitor solution contains at least one inhibitor compound and may contain multiple inhibitor compounds for forming the pattern inhibitor layer 220. The inhibitor solution may contain a self-assembled monolayer (SAM) compound, such as a hydrophobic SAM compound, for example, octadecyltrichlorosilane (ODTS) or derivatives thereof. The hydrophobic SAM compound is transferred or otherwise delivered by the stamp or other device to the first portion 212 of the back surface 206 to form the pattern inhibitor layer 220 thereon. In another example, the pattern inhibitor layer 220 is formed during a screen-printing process. The screen-printing process includes spraying or applying an inhibitor solution to the first portion 212 of the back surface 206 while printing or otherwise forming the pattern inhibitor layer 220 thereon.

The SAMs contained within the pattern inhibitor layer 220 are thin organic films which form spontaneously on solid surfaces, such as the back surface 206 of the substrate 202. The SAMs provide modifications to the physical, chemical, and electrical properties of the first portion 212 of the back surface 206. The SAMs are utilized to modify the chemical properties of the first portion 212 by covering the hydrophilic silicon surface and providing a hydrophilic surface on the first portion 212 of the back surface 206. The hydrophilic surface protects the underlying silicon surface in the first portion 212 while enabling the selective deposition on the unprotected silicon surface in the second portion 214 during the S-ALD process. Generally, the SAMs provide control of adhesion and/or wetting (such as hydrophobic SAMs) within the first portion 212 of the back surface 206. Therefore, the pattern inhibitor layer 220 is formed on the first portion 212 and inhibits the deposition of aluminum oxide on the first portion 212 during the S-ALD process at step 130. Hydrophobic SAMs, such as ODTS and the alike, form a robust, covalent Si—O linkage between each molecule of SAM and the silicon-containing surface, such as the first portion 212 of the back surface 206. The pattern inhibitor layer 220 containing ODTS or derivatives thereof demonstrates good chemical and thermal stability and provides an efficient monolayer resist for various S-ALD processes utilized to deposit aluminum oxide.

Step 130 of process 100 includes depositing or otherwise forming the passivation layer 230 containing aluminum oxide on the second portion 214 of the back surface 206 of the substrate 202 during the S-ALD process, as illustrated in FIG. 2D. The S-ALD process also includes leaving the pattern inhibitor layer 220 substantially free of aluminum oxide while depositing the passivation layer 230 in step 130. FIG. 2D depicts substrate 202 having a passivation layer 230 disposed within a passivation pattern on the second portion 214 of the back surface 206. The passivation layer 230 is deposited or otherwise formed by sequentially exposing the second portion 214 of the back surface 206 to an aluminum precursor gas and an oxidizing reagent gas to form an aluminum oxide material during the S-ALD process.

The patterned ODTS transferred onto the first portion 212 of the back surface 206 of the substrate 202 by pCP prevents the deposition of aluminum oxide at undesired or printed areas, such as on the second portion 214 of the back surface 206. The thin films of aluminum oxide contained within the passivation layer 230 are selectively deposited by S-ALD onto areas of the substrate 202 that are not deactivated or otherwise protected by the inhibitor compound (e.g., ODTS) contained within the pattern inhibitor layer 220.

The passivation layer 230 generally has a thickness within a range from about 1 nm to about 500 nm, more narrowly within a range from about 5 nm to about 200 nm, and more narrowly within a range from about 20 nm to about 80 nm. The aluminum oxide material contained within passivation layer 230 may have one layer or a plurality of layers of the same or different compositions. The aluminum oxide materials described herein may be stoichiometric aluminum oxide (e.g., Al₂O₃), metal-rich or oxygen-poor aluminum oxide (e.g., Aₓ, where 0.8<x<1.5), and/or aluminum oxide containing one or more dopants or additional elements, such as yttrium, silicon, nitrogen, hafnium, or combinations thereof.

In step 130, the aluminum precursor gas absorbs onto the second portion 214 of the back surface 206 to form a monolayer of the aluminum precursor during a first half cycle of the S-ALD process. Additionally, the aluminum precursor gas does not absorb or does not substantially absorb on the pattern inhibitor layer 220 during the first half cycle of the S-ALD process. Thereafter, the oxidizing reagent gas is exposed to and chemically reacts with the absorbed monolayer of the aluminum precursor during a second half cycle of the S-ALD process. A layer of aluminum oxide is selectively formed on the second portion 214 of the back surface 206 as the passivation layer 230, but not formed on the pattern inhibitor layer 220. Generally, the ALD chamber is purged between each half cycle of the S-ALD process, including after the first half cycle and/or the second half cycle. The ALD chamber may be purged by flowing a purge gas or a carrier gas through the chamber and over the substrate 202 and/or reducing the pressure of the chamber by vacuum. Alternatively, the S-ALD process may be performed by introducing the oxidizing reagent gas during the first half cycle of the S-ALD process and introducing the aluminum precursor gas during the second half cycle of the S-ALD process. The first and second half cycles and/or the purge steps are sequentially repeated until obtaining the desired thickness of the passivation layer 230.

The aluminum precursor gas may contain an alkyl aluminum compound, an alkoxy aluminum compound, an aluminum halide compound, an alkyl aluminum halide compound, an alkoxy aluminum halide compound, derivatives thereof, or combinations thereof. The oxidizing reagent gas may contain water, oxygen, nitrous oxide, ozone, hydrogen peroxide, alcohols, derivatives thereof, or combinations thereof. In some examples, the aluminum precursor gas contains an alkyl aluminum compound, such as trimethyl aluminum and the oxidizing reagent gas contains water vapor. Chemical precursors, ALD process parameters, deposition chambers, and various hardware components that may be utilized to form aluminum oxide materials by ALD for passivation layer 230 are disclosed in commonly assigned U.S. Pat. No. 6,620,670 and U.S. Pub. No. 2003-0198754, which are incorporated herein by reference.

In step 140 of process 100, the method includes removing the pattern inhibitor layer 220 from the back surface 206 to expose or reveal the first portion 212 of the back surface 206, as illustrated in FIG. 2E. The first portion 212 of the back surface 206 is encompassed by the passivation layer 230 disposed on the second portion 214 of the back surface 206. Therefore, the first portion 212 of the back surface 206 generally has a contact pattern, such as the desired pattern of the contact layer 240 post formation.

In some examples, the pattern inhibitor layer 220 is removed from the back surface 206 by dissolving the pattern inhibitor layer 220 in a solvent. The solvent utilized to dissolve or otherwise remove the pattern inhibitor layer 220 is an organic solvent, an aqueous solvent, or combinations thereof. Exemplary solvents that are useful to dissolve and remove the pattern inhibitor layer 220 include water, acetone, methyl ethyl ketone, diethyl ketone, benzene, toluene, xylene, derivatives thereof, mixtures thereof, or combinations thereof.

In step 150 of process 100, the method includes forming a contact layer 240 on the first portion 212 of the back surface 206 of the substrate 202, as illustrated in FIG. 2F. The contact layer 240 is disposed within a contact pattern on the first portion 212 of the back surface 206 and encompassed by the passivation layer 230 disposed on the second portion 214 of the back surface 206.

The contact layer 240 contains a conductive material, such as at least one metallic material, metal silicide material, or combinations thereof. Exemplary metals contained in the contact layer 240 include aluminum, silver, gold, copper, nickel, tungsten, cobalt, ruthenium, alloys thereof, silicides thereof, derivatives thereof, or combinations thereof. In some examples, the contact layer 240 contains aluminum and silver, such as an aluminum silver alloy. The contact layer 240 is formed by depositing, applying, or otherwise disposing a metallic paste or metallic solder on the first portion 212 of the back surface 206, such as within the contact pattern on the first portion 212.

In some implementations, a metallic material may be more desirable than a metal silicide material for the contact layer 240. Therefore, the metallic paste or solder is heated to a temperature below the silicidization temperature for the specific metallic element. The contact layer 240 containing a metallic material is formed within the contact pattern encompassed by the passivation layer 230 and disposed on the first portion 212 of the back surface 206. Alternatively, in other implementations, a metal silicide material may be more desirable than a metallic material for the contact layer 240. Therefore, the metallic paste or solder is heated to a temperature at or above the silicidization temperature for the specific metallic element while in contact with the silicon surface of the back surface 206. Silicon atoms from the substrate 202 react with the disposed metal atoms to form the metallic silicide material. The contact layer 240 containing the metal silicide material is formed within the contact pattern encompassed by the passivation layer 230 and disposed on the first portion 212 of the back surface 206. Further description of silicidization processes that may be utilized to form metal silicide materials described herein is disclosed in commonly assigned U.S. Pat. Nos. 6,740,585 and 7,416,979, which are hereby incorporated by reference in their entirety to the extent not inconsistent with the claimed invention.

In one example, a metallic paste containing aluminum and silver is disposed onto the silicon-containing surface of the first portion 212 of the back surface 206. During a subsequent silicidization process, the substrate 202 is heated to form the contact layer 240 containing an aluminum silver silicide.

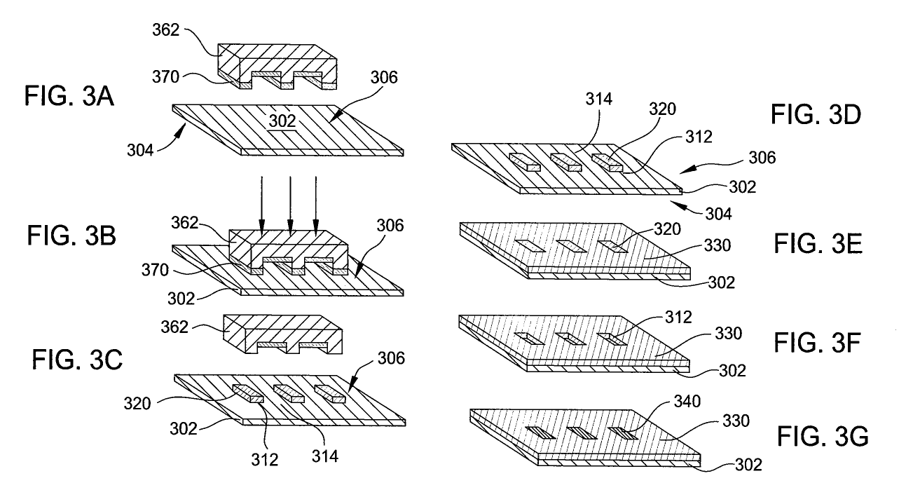

FIGS. 3A-3G depict exemplary views of a substrate 302 after being processed at different steps of a passivation and metallization process sequence, such as steps 120-150 of process 100, as described by embodiments herein. The substrate 302, the front and back surfaces 304 and 306, the first and second portions 312 and 314, the pattern inhibitor layer 320, the passivation layer 330, and the contact layer 340 depicted in FIGS. 3A-3G are analogous to the substrate 202, the front and back surfaces 204 and 206, the first and second portions 212 and 214, the pattern inhibitor layer 220, the passivation layer 230, and the contact layer 240 depicted in FIGS. 2C-2F and are similarly processed during steps 120-150 of process 100.

FIGS. 3A-3C depict exemplary views of the substrate 302 after being processed at different steps for forming a pattern inhibitor layer 320 on a first portion 312 of a back surface 306 of the substrate 302 during a microcontact-printing process, as described by some embodiments herein. The microcontact-printing process includes exposing a pattern stamp 362 to an inhibitor solution 370 and then contacting the pattern stamp 370 to the first portion 312 of the back surface 306, as depicted in FIGS. 3A-3B. The inhibitor solution 370 contained on the pattern stamp 362 forms the pattern inhibitor layer 320 on the first portion 312 of the back surface 306, as depicted on FIG. 3C. The inhibitor solution 370 contains at least one inhibitor compound and may contain multiple inhibitor compounds for forming the pattern inhibitor layer 320. The inhibitor solution 370 may contain a SAM compound, such as a hydrophobic SAM compound, for example, octadecyltrichlorosilane (ODTS) or derivatives thereof. The hydrophobic SAM compound is transferred or otherwise delivered by the pattern stamp 362 or other device to the first portion 312 of the back surface 306 to form the pattern inhibitor layer 320 thereon.

FIG. 3D depicts the substrate 302 after step 120, wherein the pattern inhibitor layer 320 is disposed on the first portion 312 of the back surface 306 of the substrate 302. FIG. 3E depicts the substrate 302 after step 130, wherein the passivation layer 330 containing aluminum oxide is disposed on the second portion 314 of the back surface 306 and encompassing the pattern inhibitor layer 320. FIG. 3F depicts the substrate 302 after step 140, wherein the pattern inhibitor layer 320 is removed from the back surface 306 to expose or reveal the first portion 312 of the back surface 306 encompassed by the passivation layer 330. FIG. 3G depicts the substrate 302 after step 150, wherein the contact layer 340 is disposed on the first portion 312 of the back surface 306 and is encompassed by the passivation layer 330.

In some embodiments described herein, the dielectric passivation and metallization process is utilized on the backside or back surface of the substrate, while in other embodiments, the process may be utilized on the front side or front surface of the substrate. The substrate may have a passivation layer on one side or both sides, such as the front surface and/or back surface of the substrate prior to the metallization. Therefore, the substrate may be a single-sided passivation and/or a double-sided passivation prior to the metallization. Additionally, other embodiments provide that the dielectric passivation and metallization process is utilized in further applications, such as transistor front end processing, light emitting diode (LED) processing, as well as other electronic device processing.

While the foregoing is directed to embodiments of the invention, other and further embodiments of the invention may be devised without departing from the basic scope thereof, and the scope thereof is determined by the claims that follow.

1. A method for forming passivation materials on a substrate, comprising:
forming a pattern inhibitor layer on a back surface of a substrate, wherein the pattern inhibitor layer covers a first portion of the back surface and a second portion of the back surface remains substantially free of the pattern inhibitor layer;
forming a passivation layer comprising aluminum oxide on the second portion of the back surface using a selective atomic layer deposition process, wherein the pattern inhibitor layer is substantially free of the material used to form the passivation layer after performing the selective atomic layer deposition process;
removing the pattern inhibitor layer from the first portion of the back surface; and
forming a contact layer on the first portion of the back surface after removing the pattern inhibitor layer.

2. The method of claim 1, wherein the pattern inhibitor layer is formed during a screen-printing process by applying an inhibitor solution to the first portion of the back surface.

3. The method of claim 3, wherein the inhibitor solution comprises a hydrophobic self-assembled monolayer compound.

4. The method of claim 1, wherein the pattern inhibitor layer is formed during a microcontact-printing process.

5. The method of claim 4, wherein the microcontact-printing process further comprises:
exposing a pattern stamp to an inhibitor solution; and
contacting the back surface of the substrate with the inhibitor solution contained on the pattern stamp to form the pattern inhibitor layer on the first portion of the back surface.

6. The method of claim 4, wherein the inhibitor solution comprises octadecyltrichlorosilane.

7. The method of claim 1, wherein the pattern inhibitor layer comprises octadecyltrichlorosilane.

8. The method of claim 1, wherein the passivation layer is formed by sequentially exposing the substrate to trimethyl aluminum and water vapor while depositing the aluminum oxide during the selective atomic layer deposition process.

9. The method of claim 8, wherein the passivation layer has a thickness within a range from about 20 nm to about 80 nm.

10. The method of claim 1, wherein the contact layer comprises aluminum and silver.

11. The method of claim 1, wherein a metallic paste comprising aluminum and silver is disposed within the first portion of the back surface while forming the contact layer.

12. The method of claim 11, further comprising heating the metallic paste to form a metallic silicide comprising aluminum silver silicide during a silicidization process, wherein the contact layer comprises the metallic silicide material.

13. The method of claim 1, wherein the pattern inhibitor layer is removed from the back surface by dissolving the pattern inhibitor layer in a solvent selected from the group consisting of water, acetone, methyl ethyl ketone, diethyl ketone, benzene, toluene, xylene, derivatives thereof, mixtures thereof, and combinations thereof.

14. The method of claim 1, wherein the first portion of the back surface has a positive pattern for the contact layer and the second portion of the back surface has a negative pattern for the passivation layer.

15. The method of claim 1, wherein the first portion of the back surface of the substrate has a surface area ratio within a range from about 2% to about 10% of the back surface.

16. The method of claim 1, wherein native oxides and contaminants are removed from the back surface of the substrate during a preclean process prior to forming the pattern inhibitor layer.

17. A method for forming passivation materials on a substrate, comprising:
forming a pattern inhibitor layer on a back surface of a substrate during a screen-printing process, wherein a positive pattern of the back surface is covered by the pattern inhibitor layer and a negative pattern of the back surface is substantially free of the pattern inhibitor layer;
forming a passivation layer comprising aluminum oxide on the back surface within the negative pattern and maintaining the pattern inhibitor layer substantially free of the passivation layer during a selective atomic layer deposition process;
removing the pattern inhibitor layer from the positive pattern of the back surface; and
forming a contact layer on the back surface within the positive pattern after removing the pattern inhibitor layer.

18. The method of claim 17, wherein the screen-printing process further comprises applying an inhibitor solution comprising octadecyltrichlorosilane to the first portion of the back surface.

19. A method for forming passivation materials on a substrate, comprising:
forming a pattern inhibitor layer on a back surface of a substrate during a microcontact-printing process, wherein a positive pattern of the back surface is covered by the pattern inhibitor layer and a negative pattern of the back surface is substantially free of the pattern inhibitor layer;
forming a passivation layer comprising aluminum oxide on the back surface within the negative pattern and maintaining the pattern inhibitor layer substantially free of the passivation layer during a selective atomic layer deposition process;
removing the pattern inhibitor layer from the positive pattern of the back surface; and
forming a contact layer on the back surface within the positive pattern after removing the pattern inhibitor layer.

20. The method of claim 19, wherein the microcontact-printing process further comprises:
exposing a pattern stamp to octadecyltrichlorosilane; and
contacting the back surface of the substrate with the inhibitor solution contained on the pattern stamp to form the pattern inhibitor layer on the first portion of the back surface.
